(19) United States
(12) Patent Application Publication
(10) Pub. No.: US 2012/0228652 A1
(43) Pub. Date: Sep. 13, 2012

(54) LED LAMP AND MANUFACTURING METHOD THEREOF

(75) Inventors: Tjong-Ren CHANG, Hsinchu City (TW); Wei-Yuan TSOU, Taoyuan County (TW); Chun-Chieh HUANG, Hsinchu City (TW); Chin-Chia CHANG, Keelung City (TW); Hui-Shan TSAI, Hsinchu County (TW)

(73) Assignee: WELLYPOWER OPTRONICS CORPORATION, Hsinchu County (TW)

(21) Appl. No.: 13/171,481

(22) Filed: Jun. 29, 2011

(30) Foreign Application Priority Data
Mar. 8, 2011 (TW) 100107802
Mar. 8, 2011 (TW) 100204094
Mar. 8, 2011 (TW) 100204097

(51) Int. Cl. H01L 33/50; H01L 33/62

(52) U.S. Cl. 257/98; 438/27; 257/E33.058; 257/E33.066

(57) ABSTRACT

An LED lamp (Light Emitting Diode) manufacturing method is disclosed. The method includes the steps as following. First, a fluorescent powder and a translucent plastic are mixed to be a mixed material, and the ratio of the fluorescent powder and the translucent plastic is below 80:100. Second, the mixed material is applied to form a lamp shell by the injection molding technology. Third, at least one LED is arranged at the center of the bottom of the lamp shell.

### RELATED APPLICATIONS

The application claims priority to Taiwan Applications Serial Number 100107802, 100204094, and 100204097, all filed Mar. 8, 2011, which is herein incorporated by reference.

### BACKGROUND

1. Field of Invention

The present invention relates to a lighting fixture. More particularly, the present invention relates to an LED (Light Emitting Diode) lamp and a manufacturing method thereof.

2. Description of Related Art

An LED is a semiconductor element. Initially, the LED is used as an indication light, a display board, and so on. However, with the appearance of white LED, the LED is also used for illumination. The LED is a new type of light source in the 21^{st} century, and has the advantages such as high efficiency, long operation life, and high stubbornness with which conventional light sources cannot compare. When a positive voltage is applied on an LED, the LED can emit discontinuous monochrome light, which is one kind of electroluminescence effect. By varying the chemical composition of the semiconductor material, the LED may emit near ultraviolet light, visible light, or infrared light.

The most common illumination LED is fabricated by combining a blue LED and yellow fluorescent powder. However, it has the disadvantage of time consuming to coat the yellow fluorescent powder onto a lamp shell enclosing the blue LED.

### SUMMARY

Hence, an aspect of the present invention is to provide a method of manufacturing an LED lamp for omitting the aforementioned process of coating the yellow fluorescent powder.

According to an embodiment of the present invention, a manufacturing method of an LED lamp is provided. The method comprises the following steps. Firstly, mixing a fluorescent powder and a translucent plastic to form a mixed material, and the ratio of the fluorescent powder to the translucent plastic is below 80:100, and then injecting the mixed material to form a lamp shell monolithically by injection molding. Thereafter, setting at least one LED at a center position of a bottom of the lamp shell.

In addition, in other embodiments, the LED can be selected from a blue LED of wavelength 445-470 nm, a red LED of wavelength 440-460 nm, a green LED of wavelength 445-460 nm, an LED of UV, and combinations thereof. On the other hand, the fluorescent powder can be selected from an orange-yellow powder, a green powder, a red powder, and combinations thereof, such as a mixture of an orange-yellow powder and a red powder. Besides, the radius of the lamp shell can be controlled within 1-60 mm and the thickness thereof within 0.1-3 mm by controlling the injection molding process of the mixed material. More specifically, the radius of the lamp shell can be further increased to enhance the color temperature of the light subsequently generated, and can be further decreased to lower the color temperature of the light subsequently generated. Furthermore, in one embodiment, oxygen and moisture contained in the lamp shell can be removed so as to increase the operation life of the LED.

Another aspect of the present invention is to provide an LED lamp with low cost.

According to the embodiment of the present invention, an LED comprises a lamp shell, a circuit board, and at least one LED. The lamp shell is formed from a mixed material of a translucent plastic material and fluorescent powder, wherein the ratio of the fluorescent powder to the translucent plastic is below 80:100. The circuit board is arranged at a center position of a bottom of the lamp shell. The LED is mounted on the circuit board.

In addition, the LED can be selected from a blue LED of wavelength 445-470 nm, a red LED of wavelength 440-460 nm, a green LED of wavelength 445-460 nm, an LED of UV, and combinations thereof. The fluorescent powder can be selected from an orange-yellow powder, a green powder, a red powder, and combinations thereof, such as a mixture of an orange-yellow powder and a red powder. Besides, a radius of the lamp shell can be 1-60 mm, and a thickness thereof can be 0.1-3 mm.

Thus, the above embodiments of the LED lamp and the manufacturing method thereof can perform the step of forming the lamp shell and the step of coating the fluorescent powder in one single step, thereby reducing the manufacturing cost and time.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a schematic diagram showing the structure of an LED lamp in accordance with an embodiment of the present invention.

FIG. 2 is a cross-sectional view of a bulb 110 in FIG. 1.

FIG. 3 is a chromaticity diagram of a lamp shell 111, the fluorescent powder and LED 113 in FIG. 2.

FIG. 4 is a flow chart showing a manufacturing method of LED lamp in accordance with another embodiment of the present invention.

### DETAILED DESCRIPTION

Reference will now be made in detail to the present embodiments of the invention, examples of which are illustrated in the accompanying drawings.

Wherever possible, the same reference numbers are used in the drawings and the description to refer to the same or like parts.

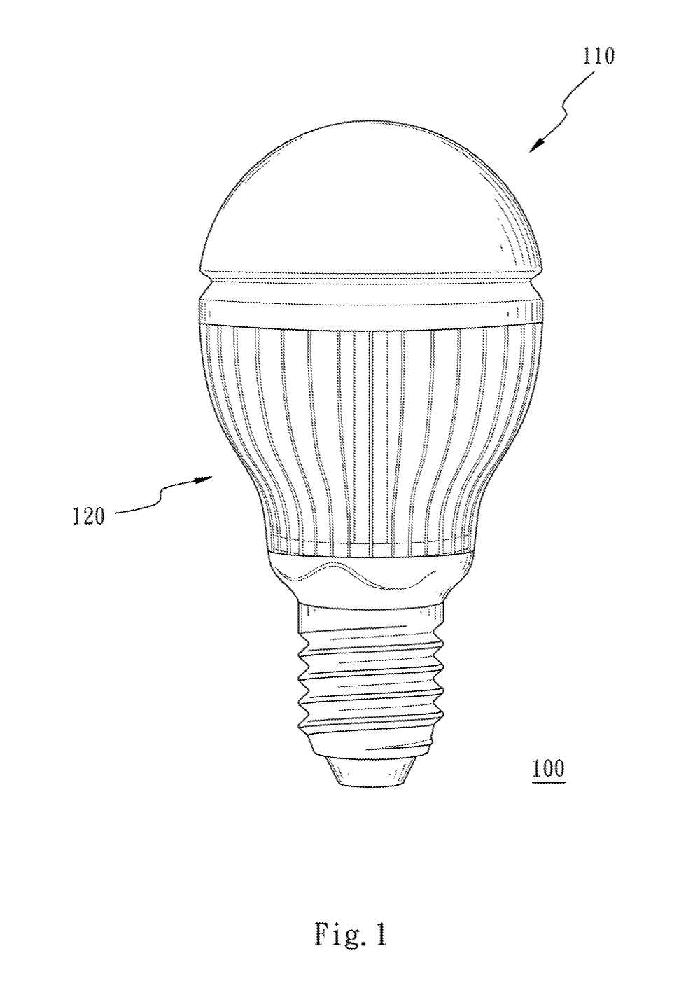

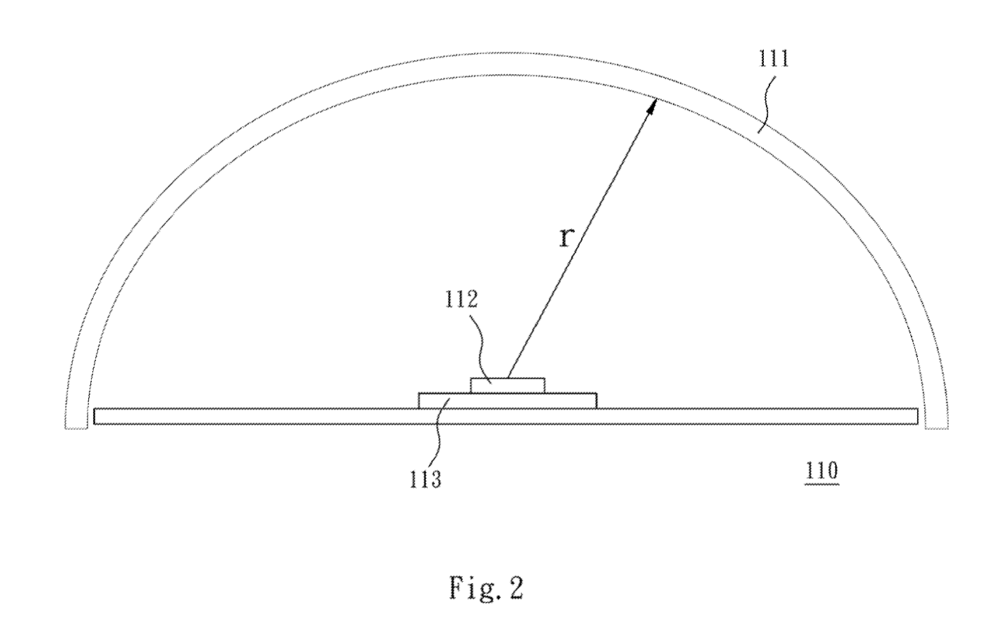

Please refer to FIG. 1 and FIG. 2. FIG. 1 is a schematic diagram showing the structure of an LED lamp in accordance with an embodiment of the present invention. In FIG. 1, an LED lamp 100 comprises a bulb 110 and a conducting cap 120. The thermal sink, such as heat fin, can be added around the conducting cap 120. FIG. 2 is a cross-sectional view of a bulb 110 in FIG. 1. It can be known from FIG. 2 that the bulb 110 comprises a lamp shell 111, a circuit board 112 and at least one LED 113. The lamp shell 111 is formed from a mixed material of a translucent plastic material and fluorescent powder, wherein the ratio of the minor fluorescent powder to the translucent plastic is below 80:100 or is between 1:1000-20:100. One aspect of the invention provides that the translucent plastic is distributed gradually from the first side of the lamp shell 111 to the second side of the lamp shell 111. That is, the density of the translucent plastic decreases from the first side to the second side. Accordingly, the fluorescent powder is distributed gradually from the second side of the lamp shell 111 to the first side of the lamp shell 111, which represents that the fluorescent powder has high density near the second side and low density near the first side, respectively.

The radius r of the lamp shell 111 is 1-60 mm and the thickness of the lamp shell 111 is 0.1-3 mm. The circuit board 112 is arranged at a center position of a bottom of the lamp shell 111, and the LED 113 is mounted on the circuit board 112. Specifically speaking, the lamp shell 111 can be a half-ellipse, that is, its cross-sectional view from up to down is a half-ellipse, and the circuit board 112 is positioned at the center of the long axis of the half-ellipse.

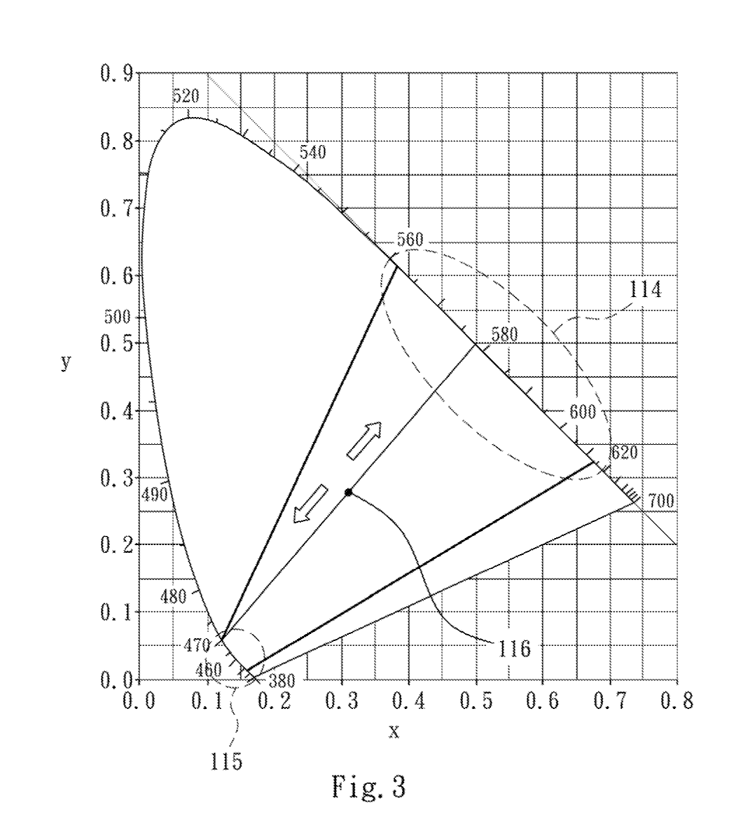

Please refer to FIG. 3. FIG. 3 is a chromaticity diagram of a lamp shell 111, the fluorescent powder and LED 113 in FIG. 2. The fluorescent powder of the lamp shell 111 can be an orange-yellow powder, a green powder, a red powder, and combinations thereof. For example, a mixed fluorescent material formed by mixing an orange-yellow powder and a red powder. In the chromaticity diagram, it corresponds to the point falling in the area 114 of 520-620 nm. On the other hand, LED 113 can be selected from a blue LED of wavelength 445-470 nm, a red LED of wavelength 440-460 nm, a green LED of wavelength 445-460 nm, and an LED of UV, and the combination thereof. For example, LED is a blue LED of wavelength 445-470 nm, the corresponding point in the chromaticity diagram is marked in area 115. In this situation, the blending light of both can be forced to fall into the trapezoidal in FIG. 3. Take a lamp shell 111 with a radius 30 mm for an example, the light generated by the whole LED lamp 100 falls in the default spot 116.

Given the above, through controlling the radius of the lamp shell 111, that is, the distance of the LED 113 and the lamp shell 111, adjustment of the default spot 116 and different color temperatures can be accomplished. When the radius of the lamp shell 111 is initialized to 30 mm, the light generated has color temperature of 6500K, as the default spot 116. When increasing the radius of the lamp shell 111, the distance of the LED 113 and the lamp shell 111 is longer, the color temperature would vary along the up-arrow to the yellow area of 2700 K. On contrast, when decreasing the radius of the lamp shell 111, the distance of the LED 113 and the lamp shell 111 is shorter, the color temperature would vary along the down-arrow to the blue area of lower color temperature.

As the radius of the lamp shell 111 is only 1 mm (small size), LED 113 can be a die and directly packaged in the lamp shell 111. Of course, as the radius of the lamp shell 111 is greater than 50 mm (large size), for arranging an LED die in the lamp shell 111, the lamp shell 111 can be vacuum or filled by inactive gas, such as argon or neon, to isolate the moisture and oxygen which may cause damage to the inner.

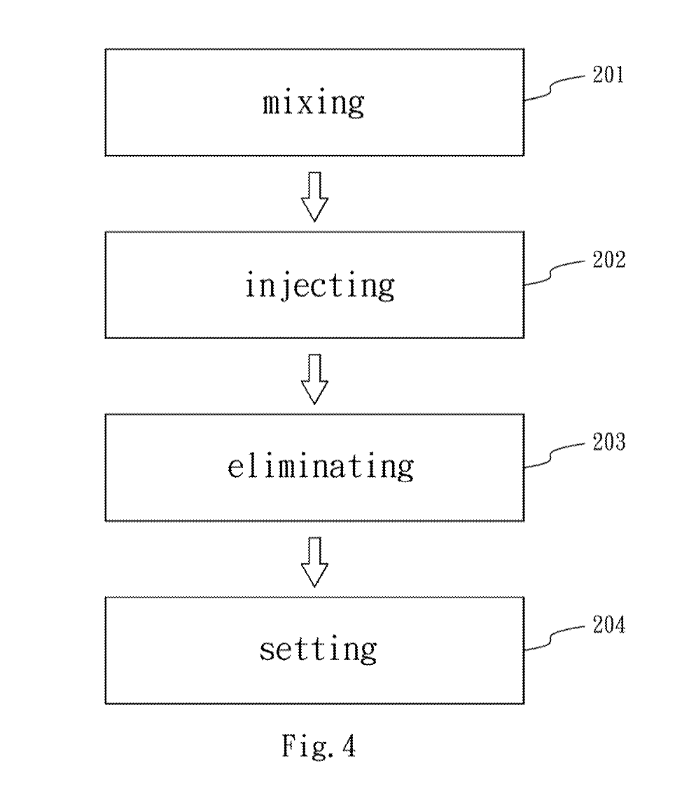

Please refer to FIG. 4. FIG. 4 is the flow chart of the manufacturing method of LED lamp in view of another embodiment of the disclosure. In FIG. 4, the manufacturing method of LED lamp comprises the following steps. Firstly, step 201: mixing a fluorescent powder and a translucent plastic to form a mixed material, and the ratio of the fluorescent powder and the translucent plastic is below 80:100, such as 1:1000-20:100. Step 202: injecting the mixed material to form a lamp shell monolithically by injection molding. Because the fluorescent powder has been mixed with the translucent plastic, the conventional coating process (injecting the translucent plastic, and then coating the fluorescent powder on it) can thus be deleted. Meanwhile, controlling the radius of the lamp shell can adjust the color temperature of light following generated. In detail, increasing/decreasing the radius of the lamp shell (1-60 mm) can enhance/lower the color temperature of light following generated. Next, step 203: removing the oxygen and moisture in the lamp shell, as letting the lamp shell 111 be vacuum or filled by inactive gas, such as argon or neon, to isolate the moisture and oxygen which may cause damage to the inner. Finally, step 204: setting at least one LED (ex. LED die) at a bottom center position of the lamp shell.

Although the present invention has been described in considerable detail with reference to certain embodiments thereof, other embodiments are possible. Therefore, the spirit and scope of the appended claims should not be limited to the description of the embodiments contained herein.

What is claimed is:

1. An LED lamp, comprising:
a lamp shell, formed from a mixed material of a translucent plastic and fluorescent powder, the ratio of the fluorescent powder and the translucent plastic is below 80:100;
a circuit board, arranged at the center position of the bottom of the lamp shell; and
at least one LED, mounted on the circuit board.

2. The LED lamp of claim 1, wherein the LED is selected from a blue LED of wavelength 445-470 nm, a red LED of wavelength 440-460 nm, a green LED of wavelength 445-460 nm, and an LED of UV, and combinations thereof.

3. The LED lamp of claim 2, wherein the LED is a die and mounted near the center of the circuit board.

4. The LED lamp of claim 1, wherein the fluorescent powder is selected from an orange-yellow powder, a green powder, a red powder, and combinations thereof.

5. The LED lamp of claim 3, wherein the fluorescent powder is made by mixing an orange-yellow powder and a red powder.

6. The LED lamp of claim 1, wherein a radius of the lamp shell is 1-60 mm.

7. The LED lamp of claim 1, wherein a thickness of the lamp shell is 0.1-3 mm.

8. A manufacturing method of an LED lamp, comprising the steps:
mixing a fluorescent powder and a translucent plastic to form a mixed material, and the ratio of the fluorescent powder and the translucent plastic is below 80:100;
injecting the mixed material to form a lamp shell monolithically by injection molding; and
setting at least one LED at a center position of the bottom lamp shell.

9. The manufacturing method of an LED lamp of claim 8, wherein the LED is selected from a blue LED of wavelength 445-470 nm, a red LED of wavelength 440-460 nm, a green LED of wavelength 445-460 nm, and an LED of UV, and combinations thereof.

10. The manufacturing method of an LED lamp of claim 8, wherein the fluorescent powder is selected from an orange-yellow powder, a green powder, a red powder, and combinations thereof.

11. The manufacturing method of an LED lamp of claim 10, wherein the fluorescent powder is made by mixing an orange-yellow powder and a red powder.

12. The manufacturing method of an LED lamp of claim 8, further comprising controlling the injection molding process of mixed material so that a radius of the lamp shell is 1-60 mm.

13. The manufacturing method of an LED lamp of claim 12, further comprising increasing the radius of the lamp shell to enhance the color temperature of light generated or decreasing the radius of the lamp shell to lower the color temperature of light generated.

14. The manufacturing method of an LED lamp of claim 8, further comprising controlling the injection molding process of mixed material so that a thickness of the lamp shell is 0.1-3 mm.

15. The manufacturing method of an LED lamp of claim 8, further comprising removing the oxygen and moisture in the lamp shell.
